(19) United States
(12) Patent Application Publication
(10) Pub. No.: US 2025/0169380 A1
(43) Pub. Date: May 22, 2025

(54) QUBIT CHIP DEVICE AND METHOD OF MANUFACTURING THE SAME

(71) Applicant: Samsung Electronics Co., Ltd., Suwon-si (KR)

(72) Inventors: Jaehyeong LEE, Suwon-si (KR); Jaeho SHIN, Suwon-si (KR); Insu JEON, Suwon-si (KR); Daeseok HAN, Suwon-si (KR)

(73) Assignee: Samsung Electronics Co., Ltd., Suwon-si (KR)

(21) Appl. No.: 18/623,276

(22) Filed: Apr. 1, 2024

(30) Foreign Application Priority Data
Nov. 22, 2023 (KR) 10-2023-0163695

(51) Int. Cl. H10N 69/00; H10N 60/01; H10N 60/12

(52) U.S. Cl. CPC H10N 69/00; H10N 60/0912; H10N 60/12

(57) ABSTRACT

A qubit chip device includes: a substrate; a superconducting qubit provided on the substrate; a ground plate, on the substrate, surrounding a perimeter of the superconducting qubit, and including a conductive layer on the substrate and a superconducting layer on the conductive layer; and a readout circuit electrically connected to the superconducting qubit.

### CROSS-REFERENCE TO RELATED APPLICATIONS

This application is based on and claims priority under 35 U.S.C. § 119 to Korean Patent Application No. 10-2023-0163695, filed on Nov. 22, 2023, in the Korean Intellectual Property Office, the disclosure of which is incorporated by reference herein in its entirety.

### BACKGROUND

### 1. Field

The disclosure relates to a qubit chip device and a method of manufacturing the same.

### 2. Description of Related Art

A quantum computer performs data processing by using quantum mechanical phenomena, such as quantum superposition and quantum entanglement, as an operating principle. A unit element for storing information by using a quantum mechanical principle (or such a unit of information itself) is referred to as a quantum bit or qubit. Qubits are used as a basic unit of information in a quantum computer.

As interest in quantum computers increases, research into various types of qubits has been conducted. Qubits may be implemented in various ways, for example, photon qubits, ion trap qubits, topological qubits, and superconducting qubits.

Qubits using superconductors (i.e., superconducting qubits) are practical to manufacture with integrated circuits. A qubit chip device including superconducting qubits includes various radio frequency (RF) circuits together with a Josephson junction device. Such circuits include various resonators based on a coplanar waveguide (CPW). In this type of structure, a slot mode of the CPW and crosstalk between resonance modes may occur. Therefore, there is a need for design and process methods capable of preventing the occurrence of the slot mode and the crosstalk.

### SUMMARY

Provided are a qubit chip device and a method of manufacturing the same.

Additional aspects will be set forth in part in the description which follows and, in part, will be apparent from the description, or may be learned by practice of the presented embodiments of the disclosure.

In one general aspect, a qubit chip device includes: a substrate; a superconducting qubit provided on the substrate; a ground plate, on the substrate, surrounding a perimeter of the superconducting qubit, and including a conductive layer on the substrate and a superconducting layer on the conductive layer; and a readout circuit electrically connected to the superconducting qubit.

Heat capacity of the conductive layer may be higher than heat capacity of the superconducting layer.

Thermal conductivity of the conductive layer may be higher than thermal conductivity of the superconducting layer.

The conductive layer may include Cu, Pd, graphene, or carbon nanotubes.

The superconducting layer may include NbN, NbTiN, TiN, VN, Al, Nb, Pb, α-Ta, or V.

The superconducting layer may have a thickness of 1 nm or more.

The superconducting qubit may include: a first conductive pad and a second conductive pad apart from each other on the substrate; and a Josephson junction element provided between the first conductive pad and the second conductive pad.

The readout circuit may include: a coplanar waveguide provided as a channel within the ground plate; and a signal line provided in the coplanar waveguide and electrically connected to the superconducting qubit.

In another general aspect, a qubit chip device includes: a substrate; a superconducting qubit provided on the substrate; a ground plate, on the substrate, surrounding a perimeter of the superconducting qubit, and including a stack of two or more bi-layers, each bi-layer including a superconductive layer on a conductive layer; and a readout circuit electrically connected to the superconducting qubit.

In each bi-layer, heat capacity and thermal conductivity of the conductive layer may be higher than heat capacity and thermal conductivity of the superconducting layer.

The conductive layer may include Cu, Pd, graphene, or carbon nanotubes.

The superconducting layer may include NbN, NbTiN, TiN, VN, Al, Nb, Pb, α-Ta, or V.

The superconducting layer may have a thickness of 1 nm or more.

The superconducting qubit may include: a first conductive pad and a second conductive pad apart from each other on the substrate; and a Josephson junction element provided between the first conductive pad and the second conductive pad.

The readout circuit may include: a coplanar waveguide provided as a channel in the ground plate; and a signal line provided in the coplanar waveguide and electrically connected to the superconducting qubit.

In another general aspect, a method of manufacturing a qubit chip device includes: forming a conductive layer on a substrate; forming a superconducting layer on the conductive layer; forming a trench within the conductive layer and the superconductive layer, the trench exposing a top surface of the substrate, the trench formed by etching the conductive layer and the superconducting layer; and forming a superconducting qubit in the trench.

Heat capacity and thermal conductivity of the conductive layer may be higher than heat capacity and thermal conductivity of the superconducting layer.

The conductive layer may include Cu, Pd, graphene, or carbon nanotubes.

The superconducting layer may include NbN, NbTiN, TiN, VN, Al, Nb, Pb, α-Ta, or V.

The superconducting qubit may include: a first conductive pad and a second conductive pad apart from each other on the substrate; and a Josephson junction element provided between the first conductive pad and the second conductive pad.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan (overhead) view of a qubit chip device, according to one or more embodiments;

FIG. 2 illustrates a circuit equivalent of the qubit chip device of FIG. 1;

FIG. 3A is an enlarged plan view of area A of the qubit chip device of FIG. 1;

FIG. 3B is a cross-sectional view along line B-B′ of FIG. 3A;

FIG. 4A is a plan view illustrating a superconducting qubit according to one or more embodiments;

FIG. 4B is a cross-sectional view along line A-A′ of FIG. 4A;

FIG. 5A is a plan view illustrating a superconducting qubit according to one or more embodiments;

FIG. 5B is a cross-sectional view taken along B-B′ of FIG. 5A;

FIGS. 6A to 61 are cross-sectional views illustrating stages of manufacturing a qubit chip device, according to one or more embodiments; and

FIGS. 7A to 7J are cross-sectional views illustrating stages of manufacturing a qubit chip device, according to one or more embodiments.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

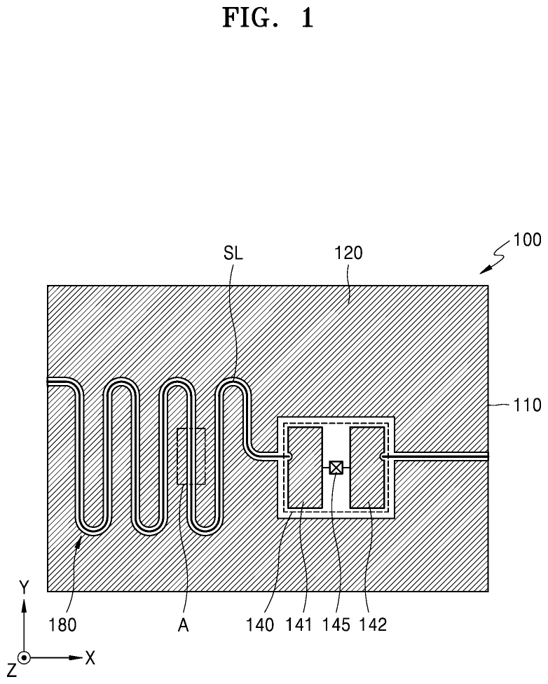

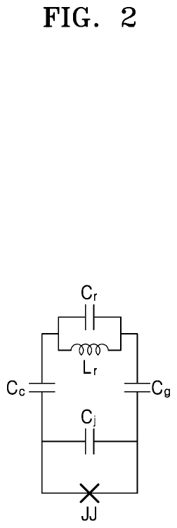

FIG. 1 is a plan (overhead) view of a qubit chip device 100 according to an embodiment and FIG. 2 illustrates a circuit equivalent of the qubit chip device 100.

The qubit chip device 100 may include a superconducting qubit 140 and a readout circuit 180 electrically connected to the superconducting qubit 140. The superconducting qubit 140 and the readout circuit 180 may be formed on a substrate 110. For convenience, one superconducting qubit 140 is illustrated in FIG. 1, however, there may be many qubits on the same chip or substrate. For example, the structures may be arranged in the Y direction and one end of each of the readout circuits 180 may be connected to an input/output line. As used herein, “superconducting”, “superconductive”, and the like refer to materials that are capable of superconducting but are not necessarily actively superconducting/superconductive.

The substrate 110 may be a silicon substrate. The substrate 110 may be, in addition to the silicon substrate, a silicon-on-insulator (SOI) substrate, a sapphire substrate, or insulating substrates composed of various materials.

The superconducting qubit 140 may include a Josephson junction. The superconducting qubit 140 may be a transmon qubit. The transmon qubit may refer to a qubit designed to have a high ratio of Josephson-energy to charge-energy so as to reduce sensitivity to charge noise. The superconducting qubit 140 may include a Josephson junction element 145. The Josephson junction element 145 may include a pair of superconducting material layers (not shown) facing each other and a non-superconducting material layer (not shown) (e.g., a dielectric layer) sandwiched between the pair of superconducting material layers. Alternatively, the Josephson junction element 145 may include a pair of superconducting material patterns facing each other and an air gap inserted between the pair of superconducting material patterns. Cooper pairs may tunnel the Josephson junction. Cooper pairs are electron pairs that do not experience electrical resistance within the superconducting material patterns. The Cooper pairs indicate the same quantum state and may be represented by the same wave function.

The superconducting qubit 140 may further include a first conductive pad 141 and a second conductive pad 142. The Josephson junction element 145 may be arranged between the first conductive pad 141 and the second conductive pad 142. The first conductive pad 141 and the second conductive pad 142 may serve as an antenna that applies an electromagnetic signal to the Josephson junction element 145 and transmits an electromagnetic signal from the Josephson junction element 145. Each of the first conductive pad 141 and the second conductive pad 142 may include a superconducting material. For example, each of the first conductive pad 141 and the second conductive pad 142 may be composed of aluminum (Al), niobium (Nb), indium (In), alpha-tantalum (α-Ta), titanium (Ti), lead (Pb), vanadium (V), or any compound thereof. For example, each of the first conductive pad 141 and the second conductive pad 142 may be composed of NbN, NbTiN, TiN, or VN. The superconducting material layer of the Josephson junction element 145 also may include the superconducting material described above.

One end (e.g., right end) of the superconducting qubit 140 may be connected to a gate electrode (not shown). For example, the second conductive pad 142 may be capacitively connected to a connector through which a gate signal is transmitted. The energy state stored in the superconducting qubit 140 may change according to the electrical signal applied from the gate electrode.

The other end (e.g., left end) of the superconducting qubit 140 may be connected to the readout circuit 180. For example, the first conductive pad 141 may be capacitively connected to a signal line SL of the readout circuit 180. The energy state of the superconducting qubit 140 may be read out through the readout circuit 180.

The readout circuit 180 may be a coplanar waveguide-based circuit. The coplanar waveguide constituting the readout circuit 180 may include the signal line SL and a ground plate 120. The signal line SL and the ground plate 120 may be formed on the same surface of the substrate 110. The ground plate 120 may have a pattern that faces the signal line SL so as to be apart from the signal line SL. The ground plate 120 may have a pattern that allows a waveguide to be formed along the signal line SL, that is, along a gap that is a space between the signal line SL and the ground plate 120.

The circuit equivalent illustrated in FIG. 2 may include a parallel connection structure of an L-C resonance circuit, a Josephson junction JJ, and a capacitor Cj. A capacitor Cg and a capacitor Cc may be connected to the L-C resonance circuit. The capacitor Cj may be formed by the first conductive pad 141 and the second conductive pad 142 that are connected to the Josephson junction element 145. A parallel connection of an inductor Lr and a capacitor Cr may be formed by the signal line SL and the ground plate 120 therearound, and the capacitor Cg and the capacitor Cc may be extracted from the relationship between the first conductive pad 141, the second conductive pad 142, and the ground plate 120.

The circuit equivalent illustrated in FIG. 2 is simplified and illustrated as including one L-C resonance circuit. The signal line SL and the ground plate 120 illustrated in FIG. 1 are represented by a plurality of L-C resonance circuits connected in series to each other. In this structure, a slot mode may occur due to an asymmetric coplanar waveguide and crosstalk may occur between adjacent resonance circuits.

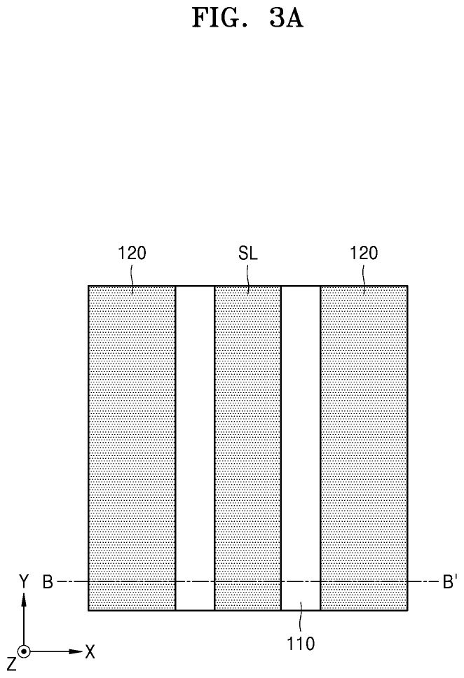

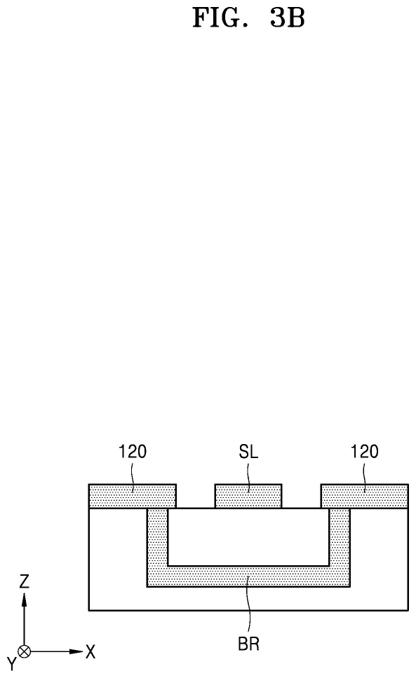

The readout circuit 180 of the qubit chip device 100 according to the embodiment may include one or more conductive bridges embedded in the substrate 110, as described below. The conductive bridge may electrically connect two portions of the ground plate 120 adjacent to (across from) each other in a direction crossing the signal line SL (i.e., on opposing sides of the signal line SL). The conductive bridge may suppress the occurrence of crosstalk or the slot mode described above, or may adjust the resonance frequency of each of the L-C resonance circuits. The conductive bridges may be provided at positions appropriate to the desired performance details and the number of conductive bridges may be determined according to the desired performance details. For example, several to dozens of conductive bridges may be provided. However, the conductive bridge is not necessarily limited to being embedded in the substrate 110 (see FIG. 3B).

In the qubit chip device 100 according to some embodiments, the signal line SL, the ground plate 120, the conductive bridge, the first conductive pad 141, and the second conductive pad 142 may each include a superconducting material and may all include the same superconducting material. The elements may be formed at the same process stage in a manufacturing process, other approaches may be used.

FIG. 3A is an enlarged plan view of a portion (portion A in FIG. 1) of the qubit chip device of FIG. 1. FIG. 3B is a cross-sectional view taken along line B-B′ of FIG. 3A.

The conductive bridge BR may be embedded in the substrate 110 and may connect two portions of the ground plate 120 to each other in a direction crossing the signal line SL, for example, in a direction crossing the signal line SL and somewhat extending in the Y direction.

FIG. 3A illustrates an arbitrary region A on the readout circuit 180 of FIG. 1, and the line B-B′ in FIG. 3A illustrates an arbitrary slice position within the region A. The region A illustrated in FIG. 1 is representative other regions of the readout circuit 180, and the conductive bridge BR may be formed at an arbitrary position within the region illustrated in FIG. 3A (i.e., at an arbitrary position along the signal line SL). The position and number of conductive bridges BR may be variously changed.

The conductive bridge BR may include a superconducting material. For example, the conductive bridge BR may include, for example, Al, Nb, In, α-Ta, Ti, Pb, V, or any compound thereof. For example, the conductive bridge BR may include NbN, NbTiN, TiN, or VN.

The conductive bridge BR and the ground plate 120 may be arranged to be in electrically direct contact with each other. As illustrated in FIG. 3B, both ends of the conductive bridge BR may be in direct contact with the ground plate 120. Such a structure may be selected when the superconducting material used in the conductive bridge BR does not undergo surface oxidation in the manufacturing process, or when there is little decrease in conductivity due to surface oxidation. NbN, NbTiN, TiN, or VN, for example, may be used as the superconducting material.

In a comparative example, the conductive bridge BR may not be provided (may be omitted), and unlike the illustrated embodiment, a ground-ground connection may be made in the form of wire bonding or air bridge. The wire bonding may provide bonding across both sides of the ground around the signal line by using, for example, an aluminum wire. The bonding work may be performed manually by using a wire bonder and may generally be performed at the last stage of mounting a completed qubit sample on a printed circuit board (PCB). Accordingly, due to the exposed delicate structure, there is a risk of damaging the qubit. In addition, the difficulty of manual work itself increases in a complicated structure in which the number of qubits increases. The air bridge is a method of forming a buffer layer of a dielectric material so as to connect both grounds except the signal line, performing patterning to enable contact with a ground portion, and depositing a metal thereon. A bridge-shaped structure that is floating above the signal line is manufactured at the last stage of the process. A layer portion of a Josephson device may be damaged in an accompanying etching process, or the air bridge or other structures may be damaged by an additional cleaning process. Due to such sensitive processes, there are limitations to controlling the thickness or width of the air bridge, and thus, unwanted capacitance or inductance may be added. It has also been reported that, when the air bridge is used, a Q-factor indicating the performance of the qubit is actually lowered.

According to an embodiment, the conductive bridge BR may be easily formed at an early stage of the manufacture process. For example, before the Josephson junction element 145 is formed and before the signal line SL and the ground plate 120 constituting the coplanar waveguide are formed, the conductive bridge BR may be manufactured so as to be embedded in the substrate 110. Therefore, there is no concern about damage or performance degradation described above. In addition, the degree of freedom in implementing the thickness or width of the conductive bridge BR, for example, the thickness in the Z direction and the width in the Y direction, is very high. The thickness of the conductive bridge BR may be tens of μm or more, for example, 20 μm or more, 30 μm or more, 50 μm or more, 100 μm or less, or 80 μm or less. The width of the conductive bridge BR, that is, the width in the direction of the length of the signal line SL, may be freely formed to a desired degree, for example, tens of μm or more, hundreds of μm or more, etc.

As the number of superconducting layers using the superconducting material increases in the qubit chip device, the shielding effect may increase and heat loss in the device process may desirably increase.

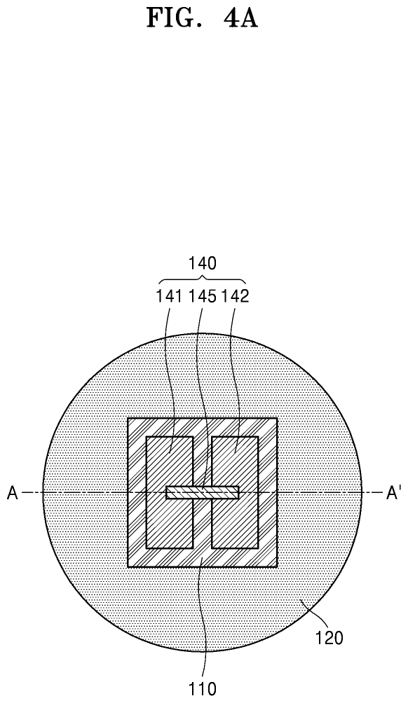

FIG. 4A is a plan view of a superconducting qubit according to an embodiment. FIG. 4B is a cross-sectional view taken along line A-A′ of FIG. 4A.

Referring to FIGS. 4A and 4B, a superconducting qubit 140 may be provided on a substrate 110. A ground plate 120 may be provided to surround the superconducting qubit 140. The ground plate 120 may include a conductive layer 121 and a superconducting layer 122 provided on the conductive layer 121.

The heat capacity and thermal conductivity of the conductive layer 121 may be higher than the heat capacity and thermal conductivity of the superconducting layer 122.

The heat capacity is the energy required to raise a temperature of a material by 1 K, and the unit of the heat capacity may be J/K. The specific heat is an inherent property of a material that varies depending on the type of material, and the heat capacity is an intrinsic quantity of a material that is defined regardless of a type of material.

The thermal conductivity is an inherent property of an object and a material with higher thermal conductivity transmits heat energy better. The unit of the thermal conductivity is W/mK. A similar concept to the thermal conductivity is thermal conductance, which refers to the degree to which an object with a specific size and shape actually transmits heat.

For example, the heat capacity of the conductive layer 121 may be 10 mJ/K or more and the heat capacity of the superconducting layer 122 may be 10 mJ/K or less. However, the disclosure is not necessarily limited thereto, and the heat capacity and thermal conductivity of the conductive layer 121 may have a heat capacity range that is higher than that of the heat capacity and thermal conductivity of the superconducting layer 122. A superconductor usually has very low heat capacity and thermal conductivity, compared to ordinary metal materials in a cryogenic temperature range of about 0 K to about 0.5 K. Accordingly, the conductive layer 121, which has a heat capacity and thermal conductivity that is higher than those of the superconducting layer 122, may have a heat capacity and thermal conductivity that are higher than those of the superconducting layer 122 in a cryogenic temperature range of about 0 K to about 0.5 K. By using material with heat capacity and thermal conductivity characteristics that decreases relatively less in the cryogenic temperature range, heat loss in the superconducting and qubit chip device may be reduced and disadvantages in terms of heat loss in the device process may be overcome. This may be applied to expand the scalability of the superconducting qubit and may be used in various superconducting and low-temperature devices.

The conductive layer 121 may include at least one of Cu, Pd, graphene, and carbon nanotubes, as non-limiting examples. Specifically, the conductive layer 121 may include a material that has a heat capacity that is higher than that of the material included in the superconducting layer 122. The conductive layer 121 may cover all or part of the substrate 110, but does not necessarily need to cover the entire substrate 110.

The superconducting layer 122 may include (be composed of) at least one of NbN, NbTiN, TiN, VN, Al, Nb, Pb, α-Ta, and V. The superconducting layer 122 may be formed to cover all or part of the substrate 110. The superconducting layer 122 may include other superconducting materials, for example, a superconducting material that is prone to surface oxidation.

The superconducting layer 122 may, through proximity to the conductive layer 121, make some properties of the conductive layer 121 similar to those of the superconductor. Accordingly, the resistance of the conductive layer 121 may be reduced.

The superconducting layer 122 may have a thickness of about 1 nm to about 20 nm. Specifically, the thickness of the superconducting layer 122 may be set such that the impedance of the qubit chip device is about 50 ohms.

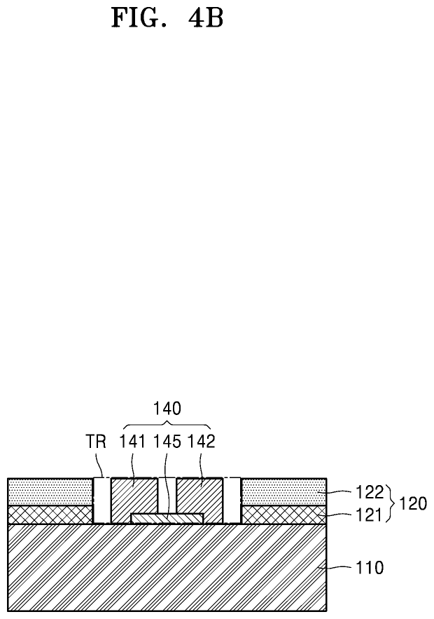

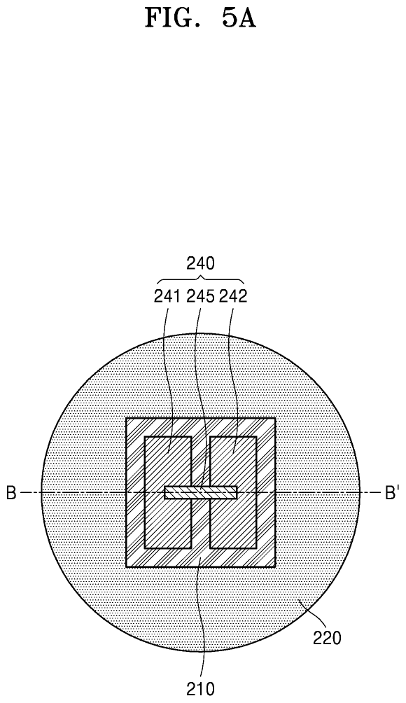

FIG. 5A is a plan view of a superconducting qubit according to one or more embodiments. FIG. 5B is a cross-sectional view taken along B-B′ of FIG. 5A.

Referring to FIGS. 5A and 5B, a superconducting qubit 240 may be provided on a substrate 210. A ground plate 220 may be provided to surround the superconducting qubit 240. The ground plate 220 may conductive layers 221 and superconducting layers 222, which are alternately stacked with the conductive layers 221.

The conductive layers 221 and the superconducting layers 222, which are alternately stacked with each other, may have improved heat capacity and thermal conductivity characteristics, compared to a qubit chip device including one conductive layer and one superconducting layer. Specifically, the number of conductive layers 221 and the number of superconducting layers 222 may each be two or more. As the number of conductive layers and superconducting layers, which are alternately stacked, increases, heat capacity and thermal conductivity characteristics may be further improved. The other qubit elements and effects are otherwise generally as described with reference to FIGS. 4A and 4B (some variations in geometry and dimensions are possible). For example, the superconducting qubit 240 may include a first conductive pad 241 and a second conductive pad 242.

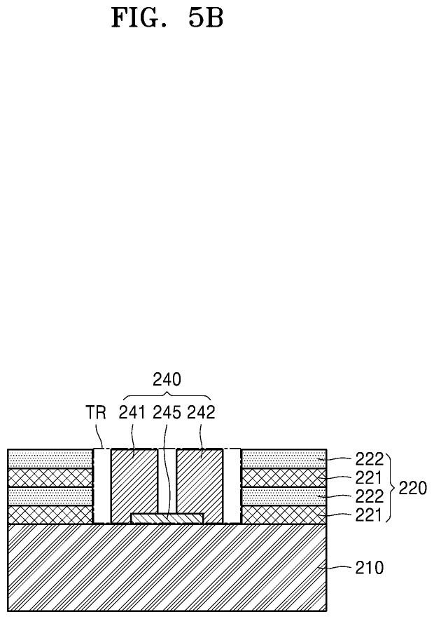

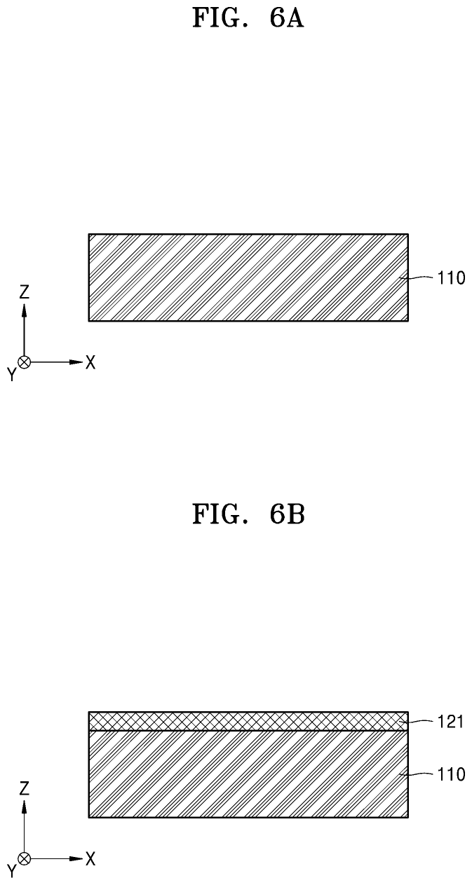

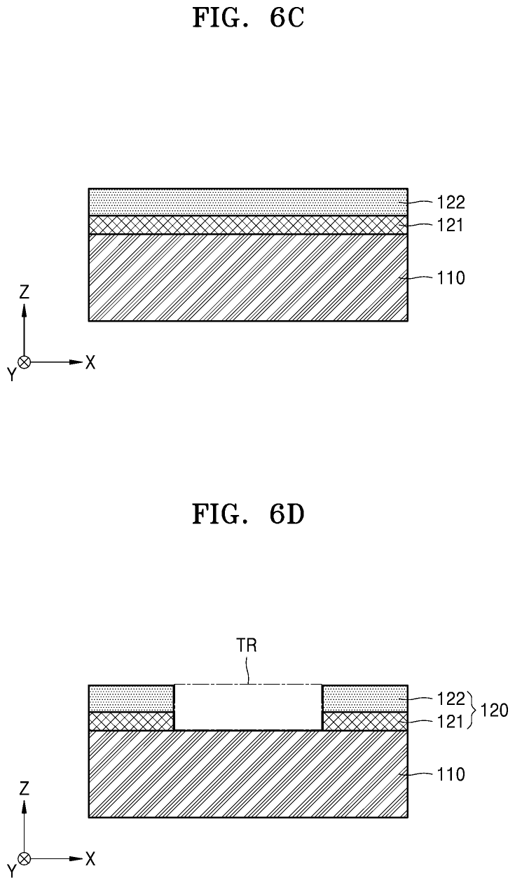

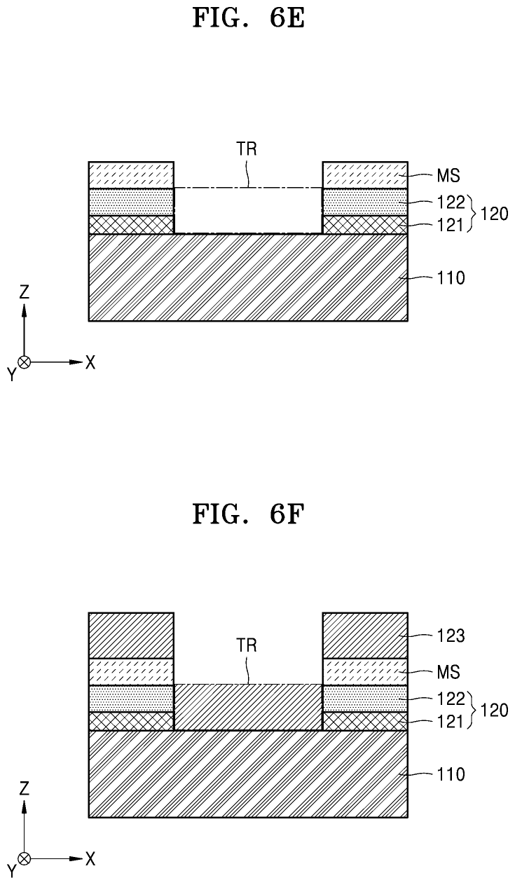

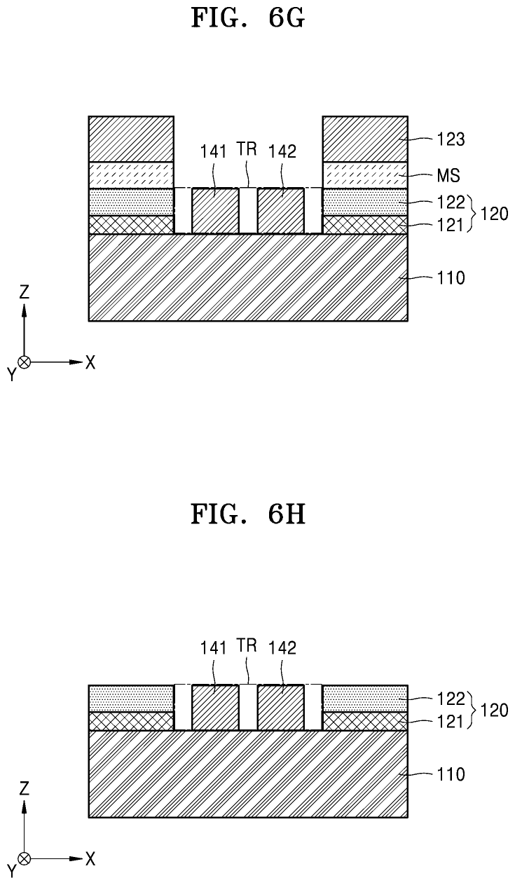

FIGS. 6A to 61 are cross-sectional views of steps of manufacturing a qubit chip device, according to one or more embodiments.

As illustrated in FIGS. 6A to 6C, a substrate 110 may be prepared. The substrate 110 may be a silicon substrate or various other insulating substrates. That is, substrates formed of various materials capable of manufacturing a coplanar waveguide, a superconducting qubit, a readout circuit, etc. on the substrate 110 according to a semiconductor process may be used. In addition, the conductive layer 121 and the superconducting layer 122 may be formed sequentially; the conductive layer 121 then the superconducting layer 122.

As illustrated in FIGS. 6D and 6E, a trench TR may be formed above the substrate 110 in the conductive layer 121 and superconducting layer 122. The spacing and size of the trench TR are only an example. For example, multiple trenches TR may be provided. In that case, the trenches may have different widths, that is, different widths in the Y direction, according to positions thereof.

The trench TR may be formed to have a desired width, length, and depth. To this end, a photolithography process and an etching process may be used. The width, length, and depth of the trench TR may be determined by taking into account the width, length, and thickness of a conductive bridge (not shown) to be manufactured. The trench TR may have a depth of several tens of μm. The trench TR, at this stage, may have a depth of about 100 μm or more.

After the trench TR is formed, a process of planarizing the inner bottom surface of the trench TR may be performed. For example, a chemical mechanical polishing (CMP) process may be performed, and then, a cleaning process may be performed.

Referring to FIG. 6F, a conductive layer 121 and a superconducting layer 122 have been configured to form in the trench TR. In addition, a sacrificial layer 123 and a mask MS may be provided thereon. The trench TR may also be filled with the material of the sacrificial layer; such material may be any suitable for conductive pads, as discussed earlier. The superconducting layer 122 may be formed by depositing the superconducting materials described above. Among the superconducting materials described above, a superconducting material that is less prone to surface oxidation may be used for the superconducting layer 122. As illustrated, the superconducting layer 122 may be formed at a certain height from the surface of the substrate 110. However, the illustrated shape is only an example and the superconducting layer 122 may have a thickness of 1 nm or more, for example.

The mask MS may be formed to be capable of producing a coplanar waveguide. In this case, the mask MS used herein is not damaged in a subsequent process and allows a superconducting device to be easily manufactured.

Referring to FIG. 6G, first and second conductive pads 141 and 142 constituting an antenna of the superconducting qubit may be formed.

Referring to FIG. 6H, the sacrificial layer 123 and the mask MS may be removed by using a material that does not damage superconductivity. As illustrated in FIG. 6I, after a process of manufacturing a Josephson junction device 145 is performed, a qubit chip device including a superconducting qubit 140 and a readout circuit may be completed.

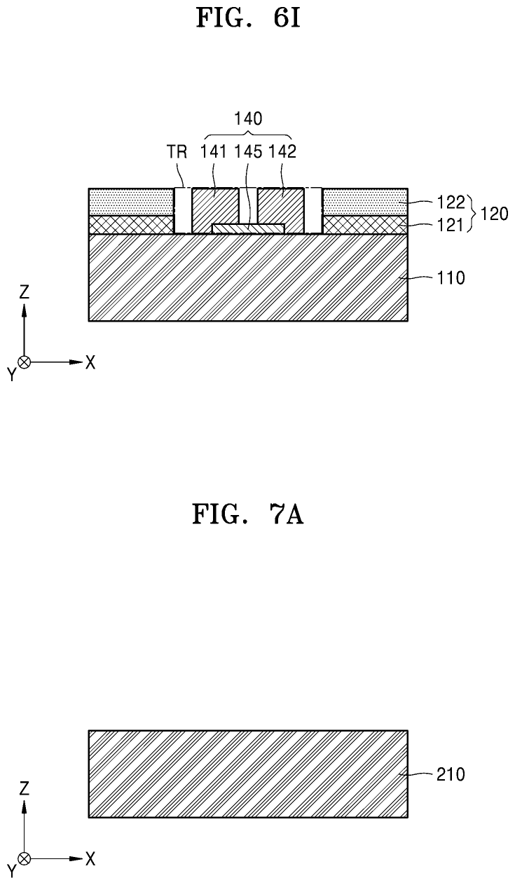

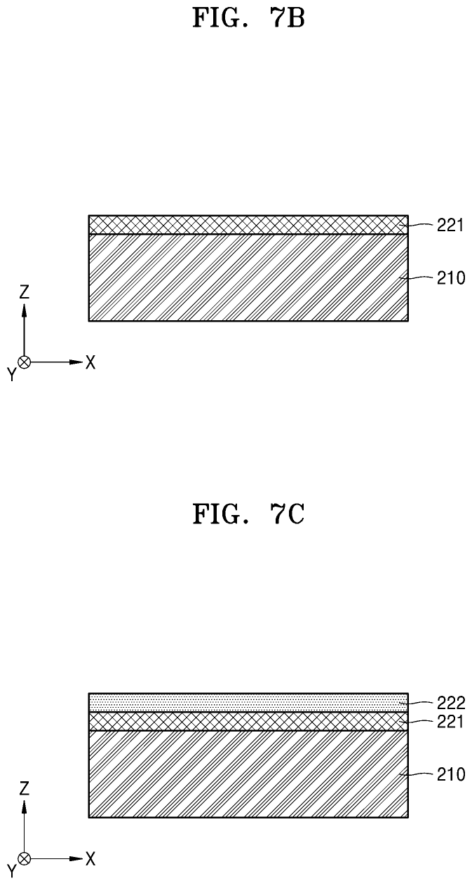

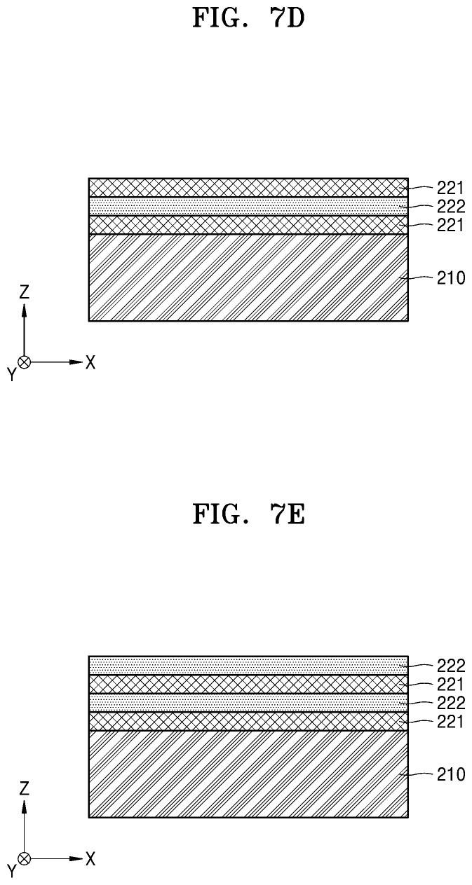

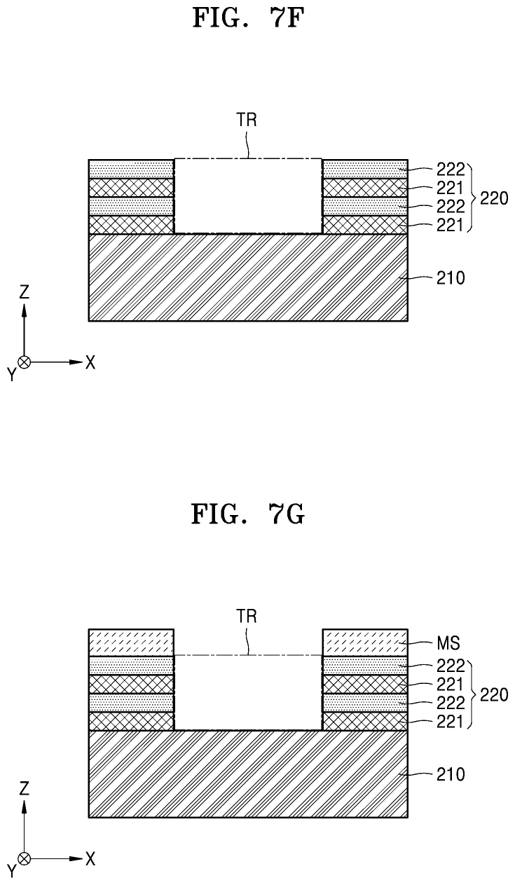

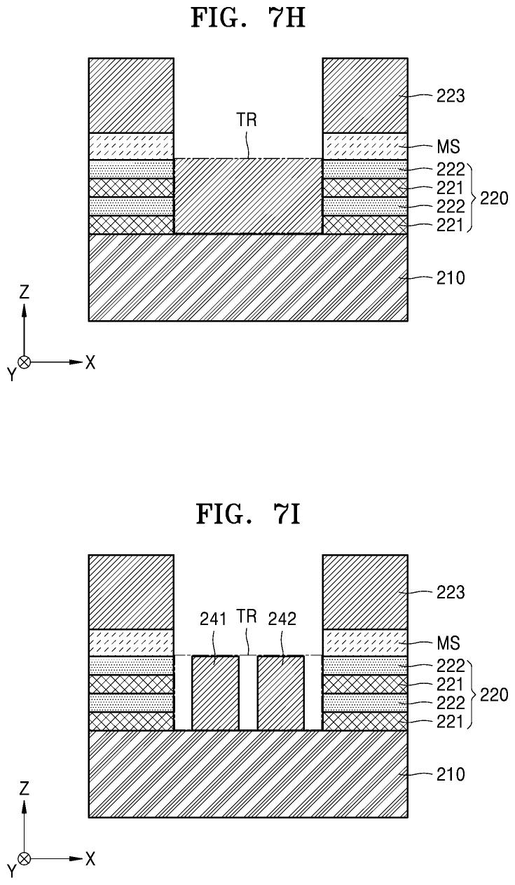

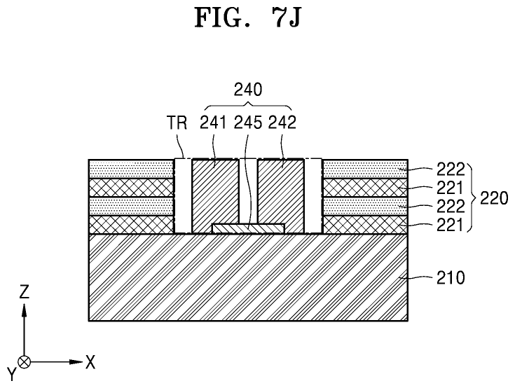

FIGS. 7A to 7J are cross-sectional views illustrating a method of manufacturing a qubit chip device, according to one or more embodiments.

As illustrated in FIG. 7A, a substrate 110 may be prepared. The substrate 110 may be a silicon substrate or various other insulating substrates. That is, substrates formed of various materials capable of manufacturing a coplanar waveguide, a superconducting qubit, a readout circuit, etc. on the substrate 110 according to a semiconductor process may be used.

As illustrated in FIGS. 7B to 7E, conductive layers 221 and superconducting layers 222 may be formed. In this case, the conductive layers 221 and the superconducting layers 222 may be alternately stacked/layered.

As illustrated in FIGS. 7F and 7G, a trench TR may be formed in the substrate 110. The spacing and size of the trench TR are only an example. For example, multiple trenches TR may be formed. The trenches TR may have different widths, that is, different widths in the Y direction, according to positions thereof.

The trench TR may be formed to have a desired width, length, and depth. To this end, a photolithography process and an etching process may be used to form the conductive layers 221 and the superconducting layers 122. The width, length, and depth of the trench TR may be determined by taking into account the width, length, and thickness of a conductive bridge (not shown) to be manufactured. The trench TR may have a depth of several tens of μm, for example. The trench TR may have a depth of about 100 μm or more, for example.

After the trench TR is formed, a process of planarizing the inner bottom surface of the trench TR may be performed. For example, a CMP process may be performed, and then, a cleaning process may be performed.

Referring to FIG. 7H, a conductive layer 221 and a superconducting layer 222 may have been formed (as discussed above) to provide the trench TR. In addition, a sacrificial layer 223 and a mask MS may be provided thereon. The material of the sacrificial layer (e.g., conductive) may also fill the trench TR. The superconducting layer 122 may be formed by depositing the superconducting materials described above. Among the superconducting materials described above, a superconducting material that is less prone to surface oxidation may be used for the superconducting layer 122. As illustrated, the superconducting layer 222 may be formed at a certain height from the surface of the substrate 210. However, the illustrated shape is only an example and the superconducting layer 222 may have a thickness of 1 nm or more, for example.

The mask MS may be formed to be capable of producing a coplanar waveguide. In this case, the mask MS used herein is not damaged in a subsequent process and allows a superconducting device to be easily manufactured.

Referring to FIG. 7I, first and second conductive pads 241 and 242 constituting an antenna of the superconducting qubit may be formed.

Referring to FIG. 7J, the sacrificial layer 223 and the mask MS may be removed by using a material that does not damage superconductivity. As illustrated in FIG. 7J, after a process of manufacturing a Josephson junction device 245 is performed, a qubit chip device including a superconducting qubit 240 and a readout circuit may be completed.

A qubit chip device according to an embodiment may include a ground plate provided to surround a superconducting qubit and a readout circuit electrically connected to the superconducting qubit. The ground plate itself may include a conductive layer and a superconducting layer provided on the conductive layer. The heat capacity and thermal conductivity of the conductive layer may be higher than the heat capacity and thermal conductivity of the superconducting layer. Accordingly, the qubit chip device may have improved heat capacity and thermal conductivity.

In a method of manufacturing a qubit chip device, according to one or more embodiments, a trench exposing a top surface of a substrate may be formed by etching a conductive layer and a superconducting layer, and a superconducting qubit may be formed in the trench. Accordingly, the superconducting qubit may be easily manufactured in a desired shape.

However, the effects of the disclosure are not limited to those described above.

The qubit chip device and the method of manufacturing the same have been described with reference to the embodiments illustrated in the drawings, but this is only an example. It will be understood by those of ordinary skill in the art that various modifications and equivalents may be made thereto. Therefore, the disclosed embodiments should be considered in an illustrative sense rather than a restrictive sense. The scope of the disclosure is indicated in the claims rather than the foregoing description, and all differences within the scope equivalent thereto should be construed as falling within the disclosure.

Although the embodiments have been described above, this is only an example and various modifications may be made thereto by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A qubit chip device comprising:
a substrate;
a superconducting qubit provided on the substrate;
a ground plate, on the substrate, surrounding a perimeter of the superconducting qubit, and comprising a conductive layer on the substrate and a superconducting layer on the conductive layer; and
a readout circuit electrically connected to the superconducting qubit.

2. The qubit chip device of claim 1, wherein heat capacity of the conductive layer is higher than heat capacity of the superconducting layer.

3. The qubit chip device of claim 2, wherein thermal conductivity of the conductive layer is higher than thermal conductivity of the superconducting layer.

4. The qubit chip device of claim 1, wherein the conductive layer includes Cu, Pd, graphene, or carbon nanotubes.

5. The qubit chip device of claim 1, wherein the superconducting layer includes NbN, NbTiN, TiN, VN, Al, Nb, Pb, α-Ta, or V.

6. The qubit chip device of claim 1, wherein the superconducting layer has a thickness of 1 nm or more.

7. The qubit chip device of claim 1, wherein the superconducting qubit comprises:
a first conductive pad and a second conductive pad apart from each other on the substrate; and
a Josephson junction element provided between the first conductive pad and the second conductive pad.

8. The qubit chip device of claim 1, wherein the readout circuit comprises:
a coplanar waveguide provided as a channel within the ground plate; and
a signal line provided in the coplanar waveguide and electrically connected to the superconducting qubit.

9. A qubit chip device comprising:
a substrate;
a superconducting qubit provided on the substrate;
a ground plate, on the substrate, surrounding a perimeter of the superconducting qubit, and comprising a stack of two or more bi-layers, each bi-layer comprising a superconductive layer on a conductive layer; and
a readout circuit electrically connected to the superconducting qubit.

10. The qubit chip device of claim 9, wherein, in each bi-layer, heat capacity and thermal conductivity of the conductive layer are higher than heat capacity and thermal conductivity of the superconducting layer.

11. The qubit chip device of claim 9, wherein the conductive layer includes Cu, Pd, graphene, or carbon nanotubes.

12. The qubit chip device of claim 9, wherein the superconducting layer includes NbN, NbTiN, TiN, VN, Al, Nb, Pb, α-Ta, or V.

13. The qubit chip device of claim 9, wherein the superconducting layer has a thickness of 1 nm or more.

14. The qubit chip device of claim 9, wherein the superconducting qubit comprises:
a first conductive pad and a second conductive pad apart from each other on the substrate; and
a Josephson junction element provided between the first conductive pad and the second conductive pad.

15. The qubit chip device of claim 9, wherein the readout circuit comprises:
a coplanar waveguide provided as a channel in the ground plate; and
a signal line provided in the coplanar waveguide and electrically connected to the superconducting qubit.

16. A method of manufacturing a qubit chip device, the method comprising:
forming a conductive layer on a substrate;
forming a superconducting layer on the conductive layer;
forming a trench within the conductive layer and the superconductive layer, the trench exposing a top surface of the substrate, the trench formed by etching the conductive layer and the superconducting layer; and
forming a superconducting qubit in the trench.

17. The method of claim 16, wherein heat capacity and thermal conductivity of the conductive layer are higher than heat capacity and thermal conductivity of the superconducting layer.

18. The method of claim 16, wherein the conductive layer includes Cu, Pd, graphene, or carbon nanotubes.

19. The method of claim 16, wherein the superconducting layer includes NbN, NbTiN, TiN, VN, Al, Nb, Pb, α-Ta, or V.

20. The method of claim 16, wherein the superconducting qubit comprises:
a first conductive pad and a second conductive pad apart from each other on the substrate; and
a Josephson junction element provided between the first conductive pad and the second conductive pad.
